(19) United States
(12) Patent Application Publication
(10) Pub. No.: US 2024/0258115 A1
(43) Pub. Date: Aug. 1, 2024

(54) SEMICONDUCTOR MANUFACTURING METHOD AND SEMICONDUCTOR MANUFACTURING APPARATUS

(71) Applicant: HITACHI HIGH-TECH CORPORATION, Minato-ku, Tokyo (JP)

(72) Inventor: Yoshihide YAMAGUCHI, Tokyo (JP)

(21) Appl. No.: 17/909,039

(22) PCT Filed: Jun. 9, 2021
(86) PCT No.: PCT/JP2021/021848

§ 371 Date: Sep. 2, 2022

(51) Int. Cl. H01L 21/311; H01L 21/67

(52) U.S. Cl. CPC H01L 21/31122; H01L 21/67069

(57) ABSTRACT

A semiconductor manufacturing method or apparatus for manufacturing a semiconductor device including a first process in which, for a semiconductor wafer having a film to be processed containing a typical metal element disposed on a surface thereof, an organometallic complex is formed on a surface of the film by increasing a temperature of the wafer after supplying an organic gas having a Lewis basic partial molecular structure into the processing chamber and adsorbing the gas onto the film, and the organometallic complex is vaporized and desorbed, and then a second process in which the organometallic complex formed on the surface of the film is vaporized and desorbed by stopping the supply of the gas and then increasing the temperature of the wafer stepwise after adsorbing the gas onto the surface of the film at a low temperature while supplying the organic gas containing the organic compound.

### TECHNICAL FIELD

The present invention relates to a semiconductor manufacturing method and a semiconductor manufacturing apparatus.

### BACKGROUND ART

A demand for size reduction, improvement in speed and performance, and power saving of most advanced semiconductor devices is increasingly accelerated. In particular, in a semiconductor device, various new materials have been adopted, and it is required to process (form into films and etch) such various materials (conductor films and insulating films) at ultrahigh accuracy of a nanometer level, that is, at a so-called atomic layer level.

An example of a technique for implementing such etching at the atomic layer level is known in related art as disclosed in PTL 1. According to this technique in the related art, in order to process an Al₂O₃ film, a HfO₂ film, or a ZrO₂ film as a film to be processed formed on a substrate with ultrahigh accuracy at the atomic layer level, a reactive gas containing a halogen such as fluorine (F) is reacted with the film to be processed so as to be converted into the corresponding fluoride, and then a gas containing an organometallic compound serving as a ligand exchange agent is supplied to react with the fluoride so as to be converted into a volatile organometallic complex compound, and the organometallic complex compound is removed by volatilization. More specifically, PTL 1 discloses that, in the case of the Al₂O₃ film, the Al₂O₃ film is subjected to highly accurate etching processing at the atomic layer level by a series of processing in which the Al₂O₃ film is reacted with the reactive gas containing F so as to be converted into AlFₓ (aluminum fluoride), the ALE, is reacted with trialkylaluminum serving as a ligand exchange agent so as to be converted into Al (CH₃) Fₓ₋₁, and the Al (CH₃) Fₓ₋₁ is volatilized and removed under heating at 200° ° C. to 300° C.

### CITATION LIST

### Patent Literature

PTL 1: JP-T-2018-500767

### SUMMARY OF INVENTION

### Technical Problem

The inventors of the present application have studied a technique of processing a material containing various elements with high precision at the nanometer level or the atomic layer level. In particular, various techniques have been studied and verified from the viewpoint of atomic layer level etching applicable to a film structure in which various materials are multiply stacked (a film structure of a multilayer film). For the film structure of the multilayer film in which the various materials are multiply stacked, an etching technique that can be performed at a relatively low temperature is considered to be necessary from the viewpoint of preventing interlayer diffusion.

Meanwhile, PTL 1 discloses a technique capable of implementing selective etching at 400° C. or lower, which is considered to be a promising technique in this respect. However, according to the study of the inventors, it has been found that the following points are not sufficiently considered, resulting in occurrence of problems.

That is, in the related art, since the two different gases, namely the reactive gas containing the fluorine (F) component and the ligand exchange agent, are used to react with the film layer to be processed such as Al₂O₃, a gas supply system and control thereof may be complicated, and thus a processing apparatus for performing etching (etching processing apparatus) may be increased in size and cost.

In addition, in this technique in the related art, gas replacement in a chamber is performed between processing with the F-containing reactive gas and processing with the ligand exchange agent in order to prevent mixing of the two gases, and a period is required for preventing mixing and reaction of these gases in the chamber. In a process in which the two gases are respectively supplied and generated, the process is stopped in a state where a reaction is stopped in a first process, and supply of a first gas is stopped until a reaction of a second process is started. Then, even when supply of a second gas is started, a second reaction is not immediately started, and it takes time to start the second process.

For this reason, a time required for processing until a required etching amount is achieved is long, and as a result, throughput of the processing may be impaired.

In addition, the volatile organometallic complex compound produced by supplying the gas as the ligand exchange agent is usually not sufficiently stable thermally. For this reason, during a period between volatilization from a surface of the film structure to be processed and discharge to the outside of the chamber, a part of the organometallic complex compound is thermally decomposed and stays in the chamber, and the organometallic complex compound becomes fine particles, reattaches to a surface of the substrate and thus becomes foreign matter, which may impair processing yield.

An object of the present invention is to provide a semiconductor manufacturing method and a semiconductor manufacturing apparatus capable of manufacturing a semiconductor device with improved processing efficiency and yield.

### Solution to Problem

In order to achieve the above object, one typical semiconductor manufacturing method of the present invention is achieved by including:
a step of placing a wafer in a processing chamber, the wafer having a film to be processed containing a typical metal element disposed on a surface thereof; a step of supplying an organic gas into the processing chamber, the organic gas containing an organic compound having a Lewis basic partial molecular structure; and a step of increasing and maintaining a temperature of the wafer, in which
the step of increasing and maintaining the temperature of the wafer includes: a volatilization step of vaporizing and desorbing an organometallic complex film formed by a reaction between the film and the organic gas containing the organic compound.

In addition, one typical semiconductor manufacturing apparatus of the present invention is achieved by including:
a container including a processing chamber therein; a stage that is disposed in the processing chamber and on which a wafer is disposed, the wafer having a film to be processed containing a typical metal element disposed on a surface thereof; a processing gas supply apparatus configured to supply an organic gas into the processing chamber, the organic gas containing an organic compound having a Lewis basic partial molecular structure; and a heating apparatus configured to heat the wafer, and
further including: a control unit configured to operate the heating apparatus so as to increase and maintain a temperature of the wafer in accordance with a supply operation of the organic gas containing the organic compound.

### Advantageous Effects of Invention

According to the present invention, it is possible to provide the semiconductor manufacturing method and the semiconductor of manufacturing apparatus capable manufacturing a semiconductor device with improved processing efficiency and yield.

Problems, configurations, and effects other than those described above will become apparent from the following description of embodiments.

### BRIEF DESCRIPTION OF DRAWINGS

FIG. 1 is a vertical cross-sectional view schematically showing an overall configuration outline of a semiconductor manufacturing apparatus according to an embodiment of the present invention.

FIG. 2 is a flowchart showing an operation flow in which the semiconductor manufacturing apparatus according to the embodiment shown in FIG. 1 processes a film layer to be processed disposed in advance on a wafer.

FIG. 3 is a time chart schematically showing an operation flow relative to a time transition when the semiconductor manufacturing apparatus according to the embodiment shown in FIG. 1 performs the processing shown in FIG. 2.

FIG. 4 is a time chart schematically showing an operation flow relative to the time transition when the semiconductor manufacturing apparatus according to the embodiment shown in FIG. 1 performs the processing shown in FIG. 2.

FIG. 5 is a time chart schematically showing an operation flow relative to a time transition of etching processing of a film to be processed on a wafer performed by a semiconductor manufacturing apparatus according to a modification of the embodiment shown in FIG. 1.

FIG. 6 is a drawing showing a molecular structural formula schematically showing an example of a molecular structure of an organic gas used as a processing gas in the embodiment or the modification of the present invention shown in FIGS. 1 to 5.

### DESCRIPTION OF EMBODIMENTS

The present inventors have conducted verification and restudies on a reaction mechanism during progress of etching of films (metal films, oxide films, and nitride films) containing various metals (transition metals and typical metals) in various states from various viewpoints, have found a phenomenon in which a highly volatile metal complex with high thermal stability is generated by one step by exposing a film to be etched to a gas having a Lewis basic partial molecular structure in a molecule, and have found that highly efficient etching can be implemented by using this phenomenon.

An organic gas containing an organic compound having a Lewis basic partial molecular structure in a molecule has an unshared electron pair, which is capable of being donated to the outside of the molecule, in a Lewis base portion thereof. The Lewis base portion donates the unshared electron pair to a positive charge of a metal element of the film to be etched, thereby forming an electron-donation+back-donation type strong coordinate bond and forming a thermally stable complex compound. In the present embodiment, an organic substance having a specific molecular structure of such a bonding type is used so as to eliminate thermal instability of an organometallic complex, which is a problem in the related art.

In addition, in a thermally stable complex compound generated in this manner, the positive charge of the metal element of the film to be etched is electrically neutralized by the unshared electron pair donated from the Lewis basic partial molecular structure contained in the etching gas. As a result, an electrostatic attractive force acting between adjacent molecules disappears, and thus volatility (sublimability) is improved. In addition, a highly volatile metal complex is generated by exposing the film to be etched to the gas having the Lewis basic partial molecular structure in the molecule. By this process, a predetermined amount of etching can be performed in a short time as compared with the related art in which a plurality of processes are performed with a reaction downtime in between, and thus processing efficiency is improved.

### Embodiment

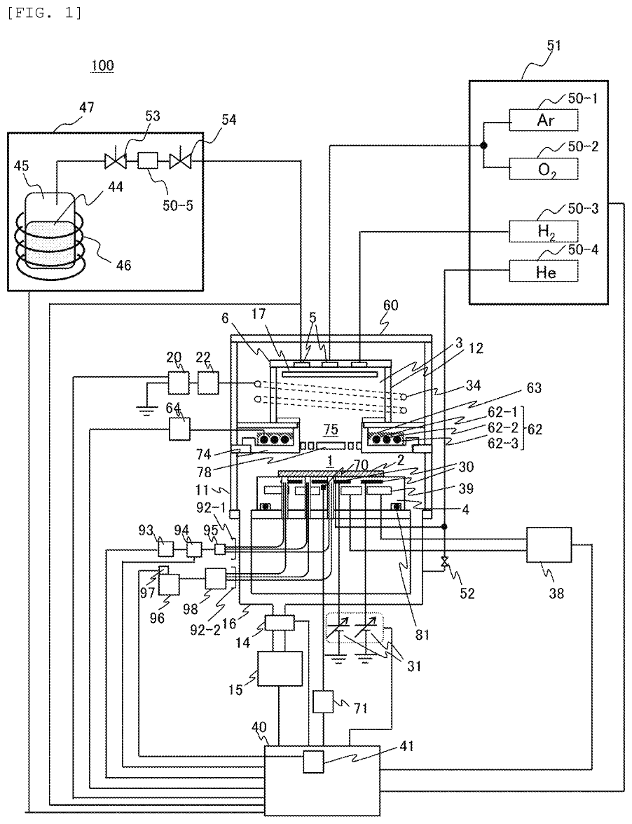

Hereinafter, an embodiment of the present invention will be described with reference to FIGS. 1 to 6. In this specification and the appended drawings, constituent elements that have substantially the same function are denoted by the same reference numerals, and repeated description thereof is omitted.

FIG. 1 is a vertical cross-sectional view schematically showing an overall configuration outline of a semiconductor manufacturing apparatus according to the embodiment of the present invention.

A processing chamber 1 is formed inside a base chamber 11 which is a metal container having a cylindrical shape, and a wafer stage 4 (hereinafter, referred to as the stage 4) on which a wafer 2 (hereinafter, referred to as the wafer 2) which is a sample to be processed is placed is provided in the processing chamber 1. In the present embodiment, an inductively coupled plasma (ICP) discharge type plasma source is used, and specifically, a plasma source including a quartz chamber 12, an ICP coil 34, and a high frequency power supply 20 is provided above the processing chamber 1. The ICP coil 34 is disposed between the quartz chamber 12 and the base chamber 11.

The present invention is not necessarily limited to an example in which ICP plasma is used, and may be implemented in a processing chamber having a minimum configuration in which the plasma source is omitted. However, in a process before or after processing targeted by the present invention, in a large number of cases, a process using ICP plasma, for example, atomic layer deposition (ALD) processing of stacking materials while precisely controlling each atomic layer, plasma enhanced atomic layer etching (ALE) processing using plasma, or the like is performed, and therefore, it is desirable to adopt an apparatus configuration in which the ICP plasma source is mounted as shown in FIG. 1.

The high frequency power supply 20 configured to generate plasma is connected to the ICP coil 34 via a matching unit 22, and a frequency band of several tens of MHz such as 13.56 MHz is used as a frequency of high frequency power thereof. A ceiling plate 6 is provided on an upper portion of the quartz chamber 12. A shower plate 5 is provided on the ceiling plate 6, and a gas dispersion plate 17 is provided below the shower plate 5. A gas (processing gas) supplied into the processing chamber 1 for processing the wafer 2 is introduced into the processing chamber 1 from an outer periphery of the gas dispersion plate 17.

The processing gas used in the present embodiment is disposed in a mass flow controller control unit 51, and a supply flow rate thereof is adjusted and controlled for each gas type by a mass flow controller (represented by 50) provided for each gas type. FIG. 1 shows a configuration example in which three types of processing gases, namely Ar, O₂, and H₂ are controlled and supplied by corresponding mass flow controllers 50-1, 50-2, and 50-3, respectively. However, there is no problem in using other processing gases not described herein, for example, halogen-based organic gases such as hydrofluorocarbon CHF, and chlorocarbon CHClₓ, and non-halogen-based organic gases such as CH₄ and CH₃OCH₃, together with mass flow controllers applied thereto.

The mass flow controller control unit 51 of FIG. 1 is a configuration example in which a mass flow controller 50-4 is also provided to adjust a flow rate of a cooling gas of He supplied between a back surface of the wafer 2 and an upper surface of a dielectric film of the stage 4 on which the wafer 2 is mounted. As another configuration example, a mass flow controller control unit configured to adjust the flow rate of He may be separately provided.

In the present embodiment, an organic gas obtained by vaporizing a liquid raw material through using an organic gas vaporization supplier (processing gas supply apparatus) 47 is used as at least a part of the processing gas. The liquid raw material may be not only a liquid at a room temperature but also a liquefied raw material obtained by melting and liquefying a solid or dissolving and liquefying in a solvent or the like. In the case of the liquefied raw material obtained by melting and liquefying the solid, the liquefied raw material can be easily vaporized by forming extremely fine particles through using an atomizer, and high concentration vapor can be easily used. In addition, in the case of the liquefied raw material obtained by dissolving and liquefying in the solvent or the like, pressure after vaporization is a sum of vapor pressure of the raw material and vapor pressure of the solvent. Conversely, supply concentration of an active component in the processing gas can be easily adjusted by dissolution and liquefaction.

Inside the organic gas vaporization supplier 47, there is a tank 45 that stores a chemical liquid 44, which is the liquid raw material. The chemical liquid 44 is heated by a heater 46 provided around the tank 45, and an upper portion of the tank 45 is filled with vapor of the chemical liquid 44. The chemical liquid 44 is a liquid serving as a raw material of an organic gas containing an organic compound having a Lewis basic partial molecular structure in a molecule, which component for converting a film containing Al₂O₃ formed on the wafer 2 into a thermally stable and volatile organometallic complex. The vapor of the chemical liquid 44 is injected into the processing chamber 1 while being controlled to have desired flow rate and speed by a mass flow controller 50-5.

While the vapor of the chemical liquid 44 is not introduced into the processing chamber 1, valves 53 and 54 are closed to shut off the chemical liquid 44 from the processing chamber 1. Further, a pipe through which the vapor of the chemical liquid 44 flows is heated or kept warm as necessary such that the vapor of the chemical liquid 44 is not condensed and does not form dew on an inner wall surface thereof, and as necessary, a heated purge gas is passed through the pipe through which the vapor of the chemical liquid 44 flows while the vapor of the chemical liquid 44 is not introduced into the processing chamber 1. Further, it is s preferable to appropriately monitor temperature and pressure of the pipe between the mass flow controller 50-5 and the processing chamber 1 so as to detect a sign of condensation and dew formation of the vapor and adjust a heating condition as necessary.

In addition, in order to avoid corrosion of the pipe caused by adsorption and occlusion of molecules of the vapor organic gas of the chemical liquid 44 on the inner wall surface of the pipe through which the vapor of the chemical liquid 44 flows, a gas purge mechanism (not shown) that passes vapor of an inert gas such as Ar or a solvent capable of dissolving the chemical liquid 44 through the pipe through which the vapor of the chemical liquid 44 flows and discharges a residual gas after the processing of supplying the vapor of the chemical liquid 44 from the mass flow controller 50-5 to the processing chamber 1 is completed, and a mechanism (not shown) configured to maintain the inside of the pipe in a vacuum state after the gas purge are also provided. By such mechanisms (the gas purge mechanism and the vacuum mechanism), even if the vapor of the chemical liquid 44 is condensed and forms dew in the pipe, an adverse effect on subsequent processing of the wafer can be minimized.

A lower portion of the processing chamber 1 is connected to an exhaust mechanism 15 by a vacuum exhaust pipe 16 in order to depressurize the processing chamber. The exhaust mechanism 15 is constituted by, for example, a turbo molecular pump, a mechanical booster pump, or a dry pump. In addition, a pressure adjustment mechanism 14 is provided upstream of the exhaust mechanism 15, the pressure adjustment mechanism 14 including a plurality of plate-shaped flaps that are disposed to have an axis in a direction crossing an exhaust flow path and rotate around the axis, or a plate member that moves across an axial direction inside the exhaust flow path. The pressure adjustment mechanism 14 can adjust a flow rate of an inside gas or particles of plasma 10 discharged from the processing chamber 1 by an operation of the exhaust mechanism 15 by increasing or decreasing a flow path cross-sectional area which is a cross-sectional area in a plane perpendicular to an axial direction of the vacuum exhaust pipe 16, thereby adjusting pressure of the processing chamber 1 and a discharge region 3.

An IR lamp unit of the present embodiment constitutes a heating apparatus, and includes an IR lamp 62 disposed in a ring shape above an upper surface of the stage 4, a reflection plate 63 that is disposed above the IR lamp 62 so as to cover the IR lamp 62 and reflects electromagnetic waves including wavelength ranges of visible light and infrared light emitted from the IR lamp 62, and a light transmission window 74. In the present embodiment, by optimizing relative positions of the IR lamp 62 and the reflection plate 63, variation in illuminance on a front surface of the wafer 2 placed on a placement surface is prevented. Further, in order to reduce the variation in illuminance, a microlens array optical system (not shown) may be disposed in at least one portion of the light transmission window 74.

As the IR lamp 62 of the present embodiment, a lamp having a multiple circular tube shape arranged concentrically or spirally around an up-down direction central axis of the base chamber 11 or the stage 4 that has a cylindrical shape is used, and other configurations may also be used as long as heating of the wafer 2 suitable for the processing can be implemented. It is assumed that the electromagnetic waves emitted from the IR lamp 62 emit electromagnetic waves mainly including light having a wavelength ranging from a visible light region to an infrared light region. Here, such light is referred to as IR light.

Although an example in which IR lamps 62-1, 62-2, and 62-3 of three laps having different diameters are coaxially provided as the IR lamp 62 is shown in the configuration shown in FIG. 1, the number of the provided IR lamps is set as desired, such as two laps or four laps or more. Further, the reflection plate 63 configured to reflect the IR light downward is provided above the IR lamp 62.

An IR lamp power supply 64 is connected to the IR lamp 62 with a high frequency cut filter (not shown) provided in the middle therebetween, the high frequency cut filter being configured to prevent noise of the high frequency power for plasma generation generated by the high frequency power supply 20 from flowing into the IR lamp power supply 64. In addition, the IR lamp power supply 64 is provided with a function of controlling power supplied to the IR lamps 62-1, 62-2, and 62-3 independently of each other, and thus a radial distribution of an irradiation amount of electromagnetic waves generated to heat the wafer 2 can be adjusted.

At a center of the IR lamp unit, a gas flow path 75 is disposed to allow the processing gas supplied from the mass flow controller 50 (50-1 to 50-3 and 50-5) to flow toward the processing chamber 1 below the quartz chamber 12. In the gas flow path 75, a slit plate (ion shielding plate) 78 is disposed, which is provided with a plurality of through holes so as to shield ions and electrons in components of plasma generated in the quartz chamber 12 and allow passage of only neutral gas and neutral radicals.

When plasma is not formed in the discharge region 3 in the quartz chamber 12, a so-called neutral gas not containing ions or electrons is used as the processing gas supplied into the quartz chamber 12 from the mass flow controller 50 (50-1 to 50-3 and 50-5). In this case, the slit plate 78 functions as a rectifying plate that rectifies a flow of the processing gas flowing into the processing chamber 1 from the gas flow path 75 by passing the flow through the through holes at predetermined positions.

In addition, size and arrangement of the through holes are appropriately arranged in such a manner that the processing gas can be preheated to a temperature suitable for the processing when the processing gas supplied from the mass flow controller 50 (50-1 to 50-3 and 50-5) passes through the through holes. Further, the slit plate 78 is disposed at an appropriate height position in the up-down direction in the gas flow path 75 surrounded by an integrally formed cylindrical portion at a central portion of the light transmission window 74 having translucency so as to exhibit the preheating function, and enables irradiation with the IR light from the IR lamp unit through the cylindrical portion.

A flow path 39 of a coolant for cooling the stage 4 is formed inside the stage 4, and the coolant is circulated and supplied to the flow path 39 by a chiller 38. In addition, in order to fix the wafer 2 to the stage 4 by electrostatic attraction, electrostatic attraction electrodes 30, which are plate-shaped electrode plates, are embedded in the stage 4, and an electrostatic attraction direct current (DC) power supply 31 is connected to each of the electrodes 30.

In addition, in order to efficiently cool the wafer 2, He gas whose flow rate and speed are appropriately adjusted by the mass flow controller 50-4 can be supplied between the back surface of the wafer 2 placed on the stage 4 and the stage 4 through a supply path in which an opening and closing valve is disposed. The He gas passes through a passage inside the stage 4 connected to the supply path and is introduced into a gap between the back surface of the wafer 2 and the upper surface of the stage 4 from an opening disposed in the upper surface of the stage 4 on which the wafer 2 is placed, thereby promoting heat transfer between the wafer 2 and the coolant flowing through the stage 4 and the flow path 39 therein.

In addition, when heating or cooling is performed while the electrostatic attraction electrode 30 is operated and the wafer 2 is electrostatically attracted, a placement surface of the upper surface of the stage 4 on which the wafer 2 is placed is coated with a resin such as polyimide so as to prevent the back surface of the wafer 2 from being rubbed and damaged or prevent dust from being generated due to a difference in thermal expansion coefficients between the wafer 2 and a member constituting the stage 4. In addition, the coating applied to at least the wafer placement surface of the stage 4 also prevents the stage 4 from being corroded or deteriorated by the processing gas supplied through the mass flow controllers 50-1, 50-2, 50-3, and 50-5, or plasma thereof.

In addition, a thermocouple 70 configured to measure a temperature of the stage 4 is provided inside the stage 4, and the thermocouple is connected to a thermocouple thermometer 71.

In addition, optical fibers 92-1 and 92-2 configured to measure a temperature of the wafer 2 are provided at three positions near a center portion of the wafer 2 placed on the stage 4, near the middle in a radial direction of the wafer 2, and near an outer periphery of the wafer 2. The optical fiber 92-1 guides IR light from an external IR light source 93 to the back surface of the wafer 2 and irradiates the back surface of the wafer 2. Meanwhile, the optical fiber 92-2 collects the IR light transmitted through and reflected by the wafer 2 among the IR light with which irradiation is performed by the optical fiber 92-1, and transmits the collected IR light to a spectroscope 96.

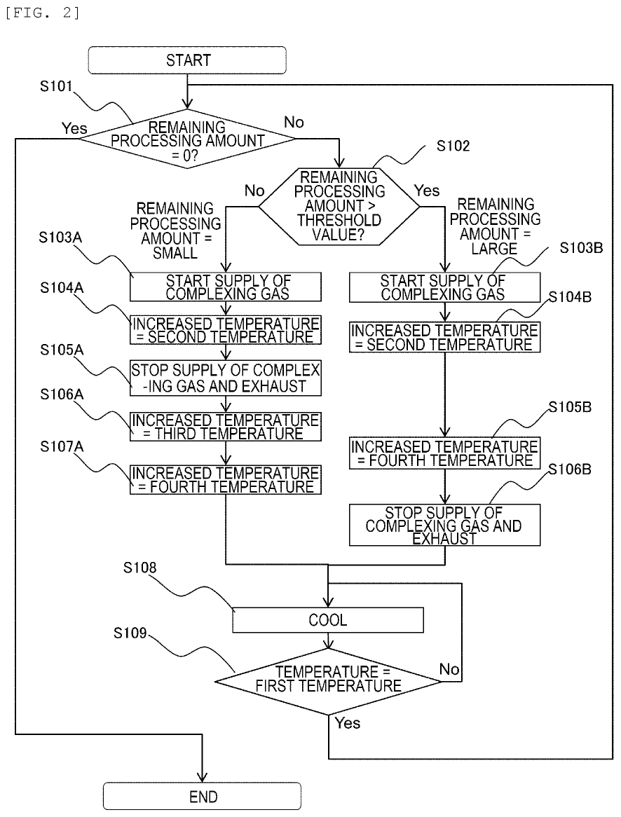

The external IR light generated by the external IR light source 93 is transmitted to an optical path switch 94 configured to turning on and off an optical path. Thereafter, each position on the back side surface of the wafer 2 is irradiated via the optical fiber 92-1 of three systems with the external IR light distributed to optical paths branched into a plurality (three in the case of FIG. 2) by an optical distributor 95.

The external IR light absorbed and reflected by the wafer 2 is transmitted to the spectroscope 96 through the optical fiber 92-2, and a detector 97 obtains wavelength dependence data of spectral intensity. Then, the obtained data of the wavelength dependence of the spectral intensity is sent to a calculation unit 41 of the control unit 40, an absorption wavelength is calculated, and the temperature of the wafer 2 can be obtained based on the calculated absorption wavelength. In addition, an optical multiplexer 98 is provided in the middle of the optical fiber 92-2. For light to be measured spectroscopically, it is possible to switch which measurement point among the center of the wafer, the middle of the wafer, and the outer periphery of the wafer, where light is to be spectroscopically measured. As a result, the calculation unit can obtain a temperature of each of the center of the wafer, the middle of the wafer, and the outer periphery of the wafer.

In FIG. 1, reference numeral 60 denotes a container covering the quartz chamber 12, and reference numeral 81 denotes an O-ring configured to vacuum-seal a space between the stage 4 and a bottom surface of the base chamber 11.

A control unit 40 controls on and off of supply of high frequency power from the high frequency power supply 20 to the ICP coil 34, and controls the mass flow controller control unit 51 to adjust type and flow rate of the gas supplied from each mass flow controller 50 into the quartz chamber 12. In this state, the control unit 40 further operates the exhaust mechanism 15 and controls the pressure adjustment mechanism 14 to adjust the inside of the processing chamber 1 to desired pressure.

Further, the control unit 40 operates the electrostatic attraction DC power supply 31 to electrostatically attract the wafer 2 to the stage 4, and operates the mass flow controller 50-4 that supplies the He gas between the wafer 2 and the stage 4. In this state, the control unit 40 controls the IR lamp power supply 64 and the chiller 38 based on the temperature inside the stage 4 measured by the thermocouple thermometer 71 and temperature distribution information of the wafer 2 obtained by the calculation unit 41 based on spectral intensity information near a center portion, near a radial middle portion, and near the outer periphery of the wafer 2 measured by the detector 97, such that the temperature of the wafer 2 falls within a predetermined temperature range.

Next, a flow in which the semiconductor manufacturing apparatus of the present embodiment processes the wafer 2 will be described with reference to FIGS. 2 to 5. FIG. 2 is a flowchart showing an operation flow in which the semiconductor manufacturing apparatus according to the embodiment shown in FIG. 1 processes a film layer to be processed disposed in advance on the wafer. In particular, in the present example, processing of etching a film containing a typical metal element (a typical metal element other than a tetravalent element such as Si or C) such as Al₂O₃ as the film layer to be processed will be described. In addition, operations such as introduction of the processing gas into the processing chamber 1 and heating of the wafer 2 by irradiation of an electromagnetic field including an IR wavelength range of the IR lamp 62, which are performed in each process of the semiconductor manufacturing apparatus 100 related to the processing, are controlled by the control unit 40.

Hereinafter, each process of processing the film layer to be processed disposed on an upper surface of the wafer 2 will be described.

In the present embodiment, a transfer robot including a plurality of arms is provided in a space inside a vacuum transfer container, which is another vacuum container connected to a cylindrical side wall of the base chamber 11 (not shown in FIG. 1). As a stage before etching processing of the wafer 2 is started, the wafer 2 held on a hand at an arm tip end of the transfer robot is transferred through the transfer space in the vacuum transfer container, passed through a gate penetrating the inside and outside of the processing chamber, and introduced into the processing chamber 1. The wafer 2 supported above the upper surface of the stage 4 is transferred to the stage 4.

The wafer 2 transferred to the stage 4 is attracted and held on the stage 4. That is, the wafer 2 disposed on the upper surface of the stage 4 and held on a dielectric film including aluminum oxide or yttrium oxide constituting the placement surface of the wafer 2 is attracted and fixed by a gripping force of an upper surface of the film caused by an electrostatic force generated by DC power supplied to a film made of metal such as tungsten disposed in the dielectric film.

On the front surface of the wafer 2, the film to be processed containing the typical metal element other than the tetravalent element, for example, an Al₂O₃ film surface, which is processed into a desired pattern shape, is formed in advance, and a part thereof is exposed. The film to be processed is formed to have a desired film thickness by using a physical vapor deposition (PVD) method, an atomic layer deposition (ALD) method, a chemical vapor deposition (CVD) method, or the like, and may also be processed by using a photolithography technique so as to have a desired pattern shape.

In the semiconductor manufacturing apparatus 100 of the present embodiment, an exposed portion of a surface of the film layer to be processed is removed by selective etching. During the selective etching, a dry etching technique as described below which does not use plasma is applied.

In a state where the wafer 2 is attracted and held on the stage 4, the He cooling gas whose flow rate is controlled by the mass flow controller 50-4 is introduced into the gap between the wafer 2 and the stage 4 from the opening portion of the stage 4, and thus heat transfer therebetween is promoted to adjust the temperature of the wafer 2.

After the wafer 2 is attracted and held on the stage 4, the inside of the processing chamber 1 is depressurized and the wafer 2 is heated. By heating the wafer 2 and increasing the temperature thereof, a gas (water vapor or the like) and foreign matter adsorbed on the front surface of the wafer 2 are desorbed. When it is confirmed that the gas component adsorbed on the front surface of the wafer 2 is sufficiently desorbed, the heating of the wafer 2 is stopped and cooling of the wafer 2 is started while the inside of the processing chamber 1 is maintained in the depressurized state. Known methods can be used for the heating and cooling in this process, and for example, known methods such as heat conduction from a heater disposed inside the stage 4 and radiation of light emitted from a lamp are used.

Other methods, for example, ashing or cleaning of the front surface by plasma formed in the processing chamber 1 may be used to remove the foreign matter attached to the wafer 2. The wafer heating process may be omitted in a case where the front surface of the wafer 2 is sufficiently clean and it is ensured that there is no adsorbed and attached matter, and it is desirable to perform the wafer heating process from the viewpoint of warming up the processing chamber 1.

The stage 4 of the present embodiment has the built-in thermocouple 70 configured to measure the temperature of the stage 4, a signal from the thermocouple 70 is converted into temperature information by the thermocouple thermometer 71, and the control unit 40 determines whether a temperature indicated by the temperature information has reached a predetermined temperature set in advance. In the present embodiment, when it is determined that the temperature has reached a first temperature (details will be described later), the etching processing is started on the film to be processed of the wafer 2.

When the control unit 40 determines that the temperature of the wafer 2 has decreased to reach the predetermined first temperature or lower, the processing of the wafer 2 is performed according to the flowchart shown in FIG. 2. Before the start of the processing, for example, before the wafer 2 is loaded into the processing chamber 1, the control unit 40 detects processing conditions such as the type and the flow rate of the gas at the time of processing the film to be processed of the wafer 2 and pressure in the processing chamber 1, that is, a so-called processing recipe.

For example, the control unit 40 acquires an ID number of each wafer 2 by a method for reading an inscription or the like of the wafer 2, and can refer to corresponding data from a production management database through a communication facility such as a network (not shown) through using the ID number. By referring to such data, it is possible to acquire data such as a history of processing of the wafer 2 corresponding to the ID number, a composition, a thickness, and a shape of the film to be processed which is a target of the etching processing, an amount of etching of the target film to be processed (target remaining film thickness, etching depth), and a condition of an end point of the etching, and select a flow of plural processing steps to be performed next according to an amount of processing to be performed on the wafer 2.

For example, it is assumed that the control unit 40 determines that the processing performed on the wafer 2 is etching processing of removing an Al₂O₃ film of 0.2 nm, which is smaller than a threshold value, for example, 0.5 nm, in which an amount (etching depth) of processing of etching the film to be processed from a thickness before the start of the processing (initial thickness) to a predetermined remaining thickness has a predetermined size 80. In this case, since ionic radii of aluminum (3+) and oxygen (2−) are approximately 0.5 angstroms and approximately 1.3 angstroms, respectively, the control unit 40 determines to execute processing of removing Al₂O₃ for substantially one atomic or molecular layer. Further, the control unit 40 transmits, to each unit constituting the semiconductor manufacturing apparatus 100, a signal for adjusting and controlling an operation of each unit so as to perform the film processing in accordance with a flow (S103A→S104A→S105A→S106A→S107A) of a process A to which the process proceeds after it is determined in a step S102 of FIG. 2 that “remaining processing amount≤threshold value” is satisfied.

On the other hand, when the control unit 40 determines that the processing on the wafer 2 is processing of etching and removing the Al₂O₃ film by a value exceeding the predetermined threshold value, for example, by a thickness of 5 nm, it is necessary to remove the Al₂O₃ layer by 10 layers or more, nearly 20 layers. In such a case, when the etching is performed on one layer at a time, the processing is repeated 10 times or more, and a processing time becomes n times longer, which may impair productivity.

Therefore, in the present embodiment, in the above case, processing of collectively removing a plurality of layers (for example, 7 to 8 layers or more) and then removing one layer at a time for remaining film layers is performed in the step S102. In the present embodiment, in such a case, processing on the film to be processed is performed at least once in accordance with a flow (S103B→S104B→S105B→S106B) of a process B to which the process proceeds after it is determined that “remaining processing amount> threshold value” is satisfied in the step S102 of FIG. 2, and then the flow (S103A→S104A→S105A→S106A→S107A) of the process A is performed, and the Al₂O₃ film is removed by a thickness of 5 nm in total in the flow of the process B and the flow of the process A.

The flowchart of FIG. 2 will be described in detail.

A first step S101 is a step of determining a remaining film thickness to be etched for the film to be processed containing the typical metal element other than the tetravalent element, for example, the Al₂O₃ film formed in advance on the upper surface of the wafer 2. In this step, in both a case where the etching processing is performed on the film to be processed for the first time after the wafer 2 is loaded and a case where the etching processing has already been performed, the control unit 40 determines the remaining film thickness of the film to be processed (hereinafter, referred to as the remaining processing amount) by appropriately referring to values of design and specification of a semiconductor device to be manufactured by using the wafer 2.

The calculation unit 41 of the control unit 40 reads software stored in a storage apparatus disposed therein, calculates a value of an amount of processing accumulated by (cumulative processing amount of) processing performed on the wafer 2 before being loaded into the processing chamber 1 and a cumulative processing amount of processing performed after being loaded into the processing chamber 1 according to an algorithm described in the software, and determines whether additional processing is necessary based on the values of the design and specification of the semiconductor device to be manufactured by using the wafer 2.

That is, when it is determined by the control unit 40 that the remaining processing amount is zero or is smaller than a predetermined value that is considered to be sufficiently small to such an extent that the remaining processing amount can be regarded as zero, the processing according to the present embodiment is ended for the film to be processed. If necessary, processing not according to the present embodiment, for example, RIE etching using ICP plasma may be performed.

In the step S101, when the control unit 40 determines that the remaining processing amount is larger than zero or the sufficiently small value, the flow proceeds to the next step S102. In the step S102, the control unit 40 compares the remaining processing amount with the predetermined threshold value 80 and determines whether the remaining processing amount is higher or lower (larger or smaller) than the predetermined threshold value 80. When it is determined that the remaining processing amount is higher than the threshold value 80, the flow proceeds to the step S103B, and when it is determined that the remaining processing amount is equal to or lower than the threshold value 80, the flow proceeds to the step S103A.

In the semiconductor manufacturing apparatus 100 according to the present embodiment, a cumulative processing amount as a result of performing the processing whose flow is shown in FIG. 2 at least once on the wafer 2 transferred to the processing chamber 1 can be easily obtained from the cumulative number of processing cycles each including steps S102 to S109 and a processing amount (processing rate) per processing cycle acquired in advance. Alternatively, the cumulative processing amount can be obtained by using analysis of the front surface of the wafer 2, an output result of a film thickness monitoring apparatus (not shown), a result of detection of a processing shape, surface roughness, or the like, or a combination thereof, and it is desirable to correct or supplement the simply calculated cumulative processing amount based on a cycle processing rate as necessary.

When it is determined by the control unit 40 in the step S102 that the remaining processing amount is larger than the predetermined threshold value, the process proceeds to the step S103B, and then a process up to the step 105B (process B) is performed. On the other hand, when it is determined by the control unit 40 in the step S102 that the remaining processing amount is equal to or smaller than the predetermined threshold value, the process proceeds to the step S103A, and then a process of the flow up to the step S107A (process A) is performed. In these steps, the etching processing of the film to be processed is performed, and the remaining film thickness is reduced.

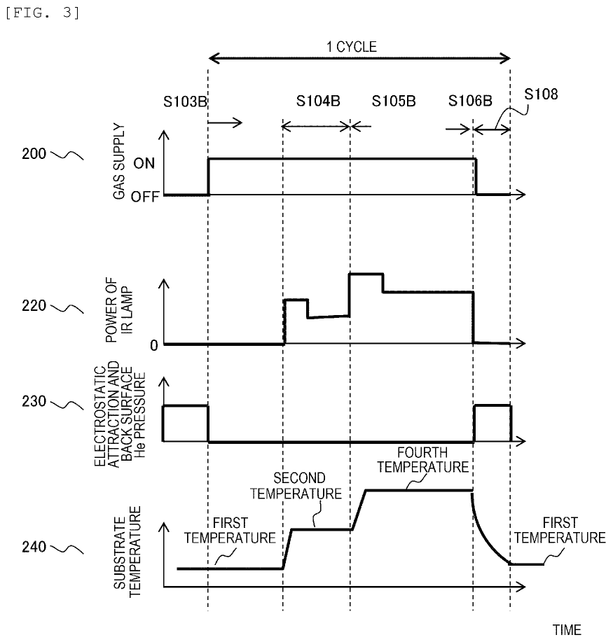

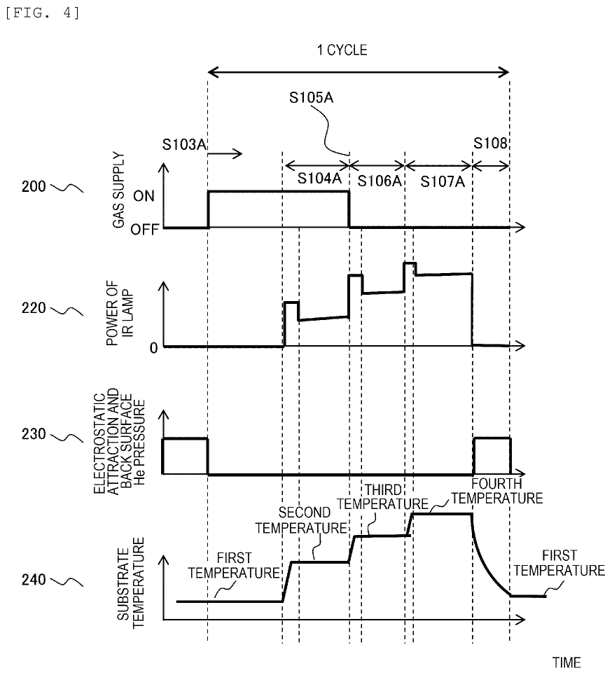

Next, the flow of processing of the wafer 2 performed by the semiconductor manufacturing apparatus 100 of the present embodiment will be described together with the operation flows of the process A and the process B with reference to FIG. 3 or 4 together with FIG. 2. FIGS. 3 and 4 are time charts each schematically showing an operation flow relative to a time transition when the semiconductor manufacturing apparatus 100 shown in FIG. 1 performs the etching processing of the film to be processed on the wafer 2 shown in FIG. 2.

In particular, FIGS. 3 and 4 are time charts when the film to be processed containing the typical metal element other than the tetravalent element is etched by the semiconductor manufacturing apparatus 100, among which FIG. 3 is a typical example of the process B performed when “remaining processing amount> threshold value” is satisfied, and FIG. 4 is a typical example of the process A performed when “remaining processing amount≤threshold” is satisfied in the step 102. These drawings schematically show the temperature of the wafer 2, and gas supply and an exhaust operation during the etching processing of the present embodiment, and actually generated temperature, temperature gradient, and necessary control time may vary depending on types of a material to be etched and a complexing material, a structure of the semiconductor device, and the like.

As described above, the thermocouple 70 configured to measure the temperature of the stage 4, the optical fibers 92 configured to detect the wafer temperature, and the like are arranged at a plurality of positions inside the stage 4, and are respectively connected to the corresponding thermocouple thermometer 71, the detector 97, and the like. However, any unit configured to appropriately measure the temperatures of the wafer 2 and the wafer stage 4 may be used instead as the temperature measuring units. When the control unit 40 detects that the temperature of the stage 4 reaches the predetermined temperature set in advance, for example, the first temperature, based on signals obtained by the temperature measuring units, one cycle of the processing of etching the film to be processed of the wafer 2 is ended.

When a determination result of the step S102 is “remaining processing amount> threshold value”, the process proceeds to the step S103B, and the supply of the vapor of the chemical liquid 44 stored in the tank 45 is started by control of the control unit 40. The vapor of the chemical liquid 44 is a component for converting the film to be processed containing the typical metal element other than the tetravalent element, for example, the Al₂O₃ film, in a semiconductor device formed on the wafer 2 placed in the processing chamber 1 into a volatile organometallic complex, and is an etching processing organic gas containing an organic compound having a Lewis basic partial molecular structure in a molecule. The organic gas obtained from the vapor of the chemical liquid 44 stored in the tank 45 is adjusted and supplied by the gas supply mass flow controller 50-5 such that the flow rate or the speed thereof becomes values within ranges suitable for the processing.

Since the organic gas is a gas that reacts with the film to be processed so as to be converted into an organometallic complex, the organic gas is hereinafter also referred to as a complexing gas. In the present embodiment, supply conditions (such as supply amount, supply pressure, supply time and gas temperature) of the complexing gas and a type of the complexing gas are selected in advance in consideration of an element composition, a shape, and a film thickness of the film to be processed containing the typical metal element other than the tetravalent element in the semiconductor device, and shape and dimension of a film structure including the film to be processed, and are selected according to the algorithm described in the software stored in the storage apparatus of the control unit 40. Further, the control unit 40 selects supply of the complexing gas according to the algorithm described in the software stored in the storage apparatus, and transmits the selected supply as a command signal to the mass flow controller 50-5 and the like for gas supply.

The step S103B is a process of forming a physical adsorption layer of complexing gas molecules on the surface of the film to be processed containing the typical metal element other than the tetravalent element, for example, the Al₂O₃ film, in the semiconductor device formed on the wafer 2. This process is performed while maintaining the temperature of the wafer 2 in a temperature range equal to or lower than a boiling point of the complexing gas.

In addition, in the present embodiment, when it is determined that the minimum required number of physical adsorption layers to be etched selected in consideration of desired accuracy and amount are formed, the process of the step S103B is ended, and is not necessary to continue for a long time. In a case where the process continues even after it is determined that the physical adsorption layers are formed, the complexing gas is consumed. A time until a desired range of the sample to be processed is covered with the minimum required number of physical adsorption layers depends on a shape of a film structure to be processed, a shape after the target processing, and the like, and therefore, it is desirable to set the time to a value including safety tolerance based on results of experiments, tests, and the like in advance before starting of a process of mass production for manufacturing the semiconductor device.

After the predetermined complexing gas is supplied in the step S103B, the process proceeds to the step S104B, and under the control of the control unit 40, power is supplied from the IR lamp power supply 64 to the IR lamp 62 in a state where the supply of the complexing gas is continued, electromagnetic waves including an infrared wavelength region are radiated, and the wafer 2 is irradiated with the electromagnetic waves. As a result, the wafer 2 is heated and the temperature thereof is quickly increased to a second temperature. In this step, the wafer 2 is heated and the temperature thereof is increased to the predetermined second temperature higher than the first temperature and maintained at the second temperature. Accordingly, the surface of the film to be processed containing the typical metal element other than the tetravalent element, for example, the Al₂O₃ film, is reactive and activated, and an adsorption state of complexing gas molecules physically adsorbed on the surface of the film changes from the physical adsorption state to a chemical adsorption state.

Further, in the next step S105B (volatilization process), under the control of the control unit 40, the wafer 2 is heated by irradiation with the IR light from the IR lamp 62 while maintaining the supply of the complexing gas to the wafer 2 in the processing chamber 1, and the temperature of the wafer 2 is increased to a fourth temperature higher than the second temperature. In this step,

(1) a first process in which an organometallic complex formed on the surface of the film to be processed containing the typical metal element other than the tetravalent element, for example, the Al₂O₃ film is volatilized, desorbed and removed from the surface of the film, and

(2) a second process in which the continuously supplied complexing gas reacts with the surface of the film to be processed containing the typical metal element other than the tetravalent element, for example, the Al₂O₃ film, and is converted into a volatile organometallic complex, are performed in parallel.

Here, the process in which the complexing gas reacts with the surface of the Al₂O₃ film and is converted into the volatile organometallic complex is referred to as a film forming process of forming an organometallic complex film. In addition, the process in which the organometallic complex film is volatilized is referred to as a volatilization process.

In the step S105B, when a specific small region on the surface of the film to be processed is microscopically viewed, removal by volatilization (desorption) of the complex on the surface of the film and conversion into and formation of a new complex proceed intermittently or stepwise in the order of (first process)→(second process)→(first process)→(second process) on the surface of the film in the region, and it can be understood that substantially continuous etching proceeds when the surface of the film to be processed is viewed as a whole.

In the step S105B, during a predetermined time, the supply of the complexing gas to the wafer 2 and the substantial continuous etching while the wafer 2 is maintained at the fourth temperature at which the organometallic complex formed in the previous step is volatilized and desorbed are continued, and then, the process proceeds to the step S106B and the supply of the complexing gas is stopped. While the processes of the steps S101 to S105B are performed, the exhaust mechanism 15 that includes an exhaust pump passing through the vacuum exhaust pipe 16 communicating with the processing chamber 1 is continuously driven to continuously exhaust the inside of the processing chamber 1, and thus gas and product particles in the processing chamber 1 are discharged to the outside of the processing chamber 1 and pressure therein is reduced.

In step S106B, since the supply of the complexing gas is stopped under the control of the control unit 40, all the gas in the processing chamber 1 containing the volatile organometallic complex derived from the film to be processed is exhausted to the outside of the processing chamber 1, and the pressure in the processing chamber 1 decreases. At this time, the unreacted complexing gas remaining in a pipe for supplying the complexing gas, for example, in a gas supply path for gas supply from the mass flow controller 50-5 to the processing chamber 1 is also discharged to the outside of the processing chamber 1 via the processing chamber 1 through the vacuum exhaust pipe 16 and the exhaust mechanism 15. Further, even after the supply of the complexing gas is stopped in the step S106B, the exhaust is continuously performed in a plurality of processes including the cooling of the wafer 2.

On the other hand, when the determination result of the step S102 is “remaining processing amount≤ threshold value”, the process proceeds to the step S103A, and the control unit 40 starts the supply of the complexing gas for converting the film that contains a transition metal on the wafer 2 disposed in the processing chamber 1 of the semiconductor manufacturing apparatus 100 into the volatile organometallic complex. After the control unit 40 detects in the step S103A that the minimum required number of physical adsorption layers are formed, the process proceeds to the step S104B, and the wafer 2 is heated by the irradiation with the IR light from the IR lamp 62, and the temperature thereof is rapidly increased to the second temperature higher than the first temperature.

As in the case of the process B, the conditions (supply amount, supply pressure, supply time, and temperature) when supplying the complexing gas and the type (composition) of the complexing gas are selected in consideration of not only the structure of the device to be manufactured but also the element composition, shape, and film thickness of the film to be processed containing the typical metal element other than the tetravalent, for example, the Al₂O₃-containing film, the film configuration in the device, the boiling point of the complexing gas, and the like, and are adjusted and set in accordance with a command signal from the control unit 40. In addition, in the step S104A, as in the case of the step S104B, the temperature of the wafer 2 is increased to the second temperature and then maintained at the second temperature, and thus the surface of the film to be processed containing the typical metal element other than the tetravalent element, for example, the Al₂O₃ film, is reactive and activated, and as a result, the adsorption state of the complexing gas is changed from the physical adsorption state to the chemical adsorption state.

By the processing of the step S104A or the step S104B, the complexing gas is chemically adsorbed on the surface of the film to be processed containing the typical metal element other than the tetravalent element, for example, the Al₂O₃ film, and in this state, the molecules of the complexing gas and typical metal atoms contained in the film to be processed, for example, Al atoms in the case where the film to be processed is the Al₂O₃ film, are firmly fixed by chemical bonding. In other words, it can be said that the complexing gas molecules are “pinned” on the surface of the typical-metal-containing film, and as a result, diffusion rate at which the complexing gas molecules diffuse from the surface of the typical-metal-containing film is slow.

The rate at which the complexing gas molecules diffuse into the Al₂O₃-containing film via a chemical adsorption layer formed on the surface of the Al₂O₃-containing film is particularly slow. Due to a leveling (surface homogenization) effect caused by the slow diffusion into the film, surface unevenness of the film to be processed is smoothened by a path from the step S103A to the step S107A.

In the next step S105A, the supply of the complexing gas is stopped under the control of the control unit 40, and the inside of the processing chamber 1 is exhausted. By exhausting the inside of the processing chamber 1, the complexing gas in an unadsorbed state or a physically adsorbed state, excluding the complexing gas chemically adsorbed on the surface of the film to be processed, is discharged to the outside of the processing chamber 1 and removed from the front surface of the wafer 2. In addition, the unreacted complexing gas remaining in the pipe for supplying the complexing gas, for example, in the gas supply path for gas supply from the mass flow controller 50-5 to the processing chamber 1 is also discharged to the outside of the processing chamber 1 via the processing chamber 1 through the gas purge mechanism (not shown) and the exhaust mechanism.

Next, in response to the command signal from the control unit 40, a radiation amount of the IR light from the IR lamp 62 continuously radiated from the step S104A is increased to increase the temperature of the wafer 2 to a third temperature equal to or higher than the second temperature (step S106A). The wafer 2 is maintained at the third temperature for a predetermined period. In this process, by increasing the temperature to the third temperature and maintaining the temperature for the predetermined period, the molecules of the complexing gas chemically adsorbed on the surface of the film to be processed containing the typical metal element other than the tetravalent element, for example, the Al₂O₃ film, are gradually converted into the volatile organometallic complex by a complexation reaction with the film to be processed on the surface of the film. In this step, as described above, the complexing gas is discharged from the processing chamber 1 except for the complexing gas that is chemically adsorbed and immobilized, an amount of an organometallic complex layer generated is substantially dominantly affected by an amount of the chemical adsorption layer, and a thickness of the organometallic complex layer is equal to or smaller than a thickness of the chemical adsorption layer.

As a next step of the present embodiment, under the control of the control unit 40, intensity of the IR light continuously emitted from the IR lamp 62 is further increased, the wafer 2 is heated, the temperature of the wafer 2 is increased to the fourth temperature higher than the third temperature, and then the temperature of the wafer 2 is maintained at the fourth temperature (step S107A: volatilization process). In this process, the temperature at which the organometallic complex formed in the previous step S106A is volatilized and desorbed is maintained, and the organometallic complex is removed from the surface of the film to be processed.

The process A constituted by a series of the plurality of processes of step S103A→step S104A→step S105A→step S106A→step S107A and the process B constituted by a series of the plurality of processes of step S103B→step S104B→step S105B→step S106B are the same in that the temperature of the wafer 2 is increased to the second temperature to generate the chemical adsorption layer on the surface of the film containing the transition metal. However, after the step of converting the chemical adsorption layer into the organometallic complex, the process A and the process B have different operations or different operation flows.

That is, when a temperature of the organometallic complex or the film having the organometallic complex on the surface thereof rises to the fourth temperature at which the organometallic complex is volatilized and removed in a state where the supply of the complexing gas is stopped, volatilization and removal of approximately one to several layers of the organometallic complex converted from the chemical adsorption layer is completed, and the reaction is terminated when the film to be processed containing the typical metal element directly below the organometallic complex is exposed to the inside of the processing chamber 1.

On the other hand, when the temperature is increased to the fourth temperature at which the organometallic complex is volatilized and removed while the supply of the complexing gas is continued, the volatilization and removal of approximately one to several layers of the organometallic complex converted from the chemical adsorption layer is completed, and when the unreacted film to be processed directly below the organometallic complex is exposed, the exposed film to be processed is heated to the fourth temperature and a degree of reaction activity is increased, so that the film to be processed is directly converted into the organometallic complex by contact with the complexing gas. Further, the generated organometallic complex is rapidly volatilized and removed, and the etching of the film to be processed as a whole proceeds continuously.

The process B constituted by the series of the plurality of processes of step S103B→step S104B→step S105B→step S106B is a reaction in which the film to be processed containing the typical metal element other than the tetravalent element, for example, the Al₂O₃ film, is directly converted into the organometallic complex, and further volatilized and removed. For this reason, a phenomenon occurs in which a very small region such as a crystal grain boundary or a specific crystal orientation that is chemically highly active and is present on the surface of the film to be processed containing the typical metal element, for example, the Al₂O₃ film, is preferentially converted into the organometallic complex and removed. In addition, when the chemical adsorption layer is formed, a process thereof is a self-organized surface orientation growth process, while in the step B, an organometallic complex layer is directly formed without undergoing the self-organized surface orientation growth process, and thus the organometallic complex layer substantially has no orientation. As a result, the surface of the film to be processed after the processing is not flattened, and rather, unevenness increases and the surface becomes roughened.

On the other hand, in the process A constituted by the series of processes of step S103A→step S104A→step S105A→step S106A→step S107A, the surface of the film to be processed containing the typical metal element after the processing, for example, the Al₂O₃ film, is flattened by the action of the self-organized orientation when the chemical adsorption layer is formed and an action of reducing the diffusion rate of the complexing gas molecules in the chemical adsorption layer that has undergone self-organized orientation growth.

In both cases of the process A and the process B, the fourth temperature of the present example is set after evaluation is performed in advance before the processing of the wafer 2 so as to be lower than a decomposition start temperature of the complexing gas molecules and a decomposition start temperature of organometallic complex molecules and higher than a evaporation start temperature of the organometallic complex molecules. In addition, when a temperature difference between the decomposition start temperature and the evaporation start temperature of the organometallic complex molecules is small and the temperature difference is insufficient in view of the specification of the semiconductor manufacturing apparatus 100, for example, characteristics of temperature uniformity in a surface direction of the upper surface of the stage 4, an existing method for reducing the evaporation start temperature of the organometallic complex molecules, for example, a method for reducing the pressure in the processing chamber 1 in order to widen a mean free path may be applied.

When the decomposition start temperature of the organometallic complex molecules is found to be lower than the evaporation start temperature based on the preliminary evaluation, a combination of a material of the film to be processed and the etching organic gas molecules is inappropriate, and therefore, another substance is re-selected from candidate materials of the etching organic gas to be described later. By actively utilizing mismatch of the combination of the material of the film to be processed and the etching organic gas molecules, only a layer of a specific material in a multilayer film structure can be selectively etched (details will be described later).

Next, the process proceeds to the step S108 and the cooling of the wafer 2 is started, and a process of reliably exhausting the complexing gas is performed before the start of the step S108. Before the start of the step S108, the supply of the complexing gas is already stopped, and the exhaust of the unreacted complexing gas remaining and staying in the pipe for supplying the complexing gas, specifically, the pipe from the mass flow controller 50-5 to the processing chamber 1 should be already completed. However, when the complexing gas remains somewhere due to certain troubles, unexpected events, or the like, there is a risk that the complexing gas may cause generation of foreign matter, and thus the operation of discharging the complexing gas by the vacuum exhaust pipe 16 and the exhaust mechanism 15 via the processing chamber 1 is performed again for precaution.

In addition, in order to eliminate a risk that the complexing gas is adsorbed on and sticked to an inner wall of the pipe, a so-called purge operation is also performed in which the inside of the pipe from the mass flow controller 50-5 to the processing chamber 1 is filled with an inert gas for exhaust before the process proceeds to the step S108. In order to reliably exhaust the gas remaining and staying in pipes for gas supply from the mass flow controllers 50-1, 50-2, 50-3, 50-4, and 50-5 to the processing chamber 1, a waste gas path (not shown) is provided as necessary.

In both cases of the flows of the processes A and B, next, the process proceeds to the step S108 to start the cooling of the wafer 2, and the cooling of the wafer 2 in the step S108 is continued until it is detected in the step S109 that the temperature of the wafer 2 has reached the predetermined first temperature.

In the step S108 of performing the wafer cooling, it is desirable to supply a cooling gas between the wafer stage 4 and the wafer 2. As the cooling gas, for example, He, Ar, or the like is suitable, and when the He gas is supplied, the cooling can be performed in a short time, so that processing productivity is improved. As described above, since the flow path (cooling circulation pipe) 39 connected to the chiller 38 is provided inside the wafer stage 4, the wafer 2 is gradually cooled even in a state where the wafer 2 is only electrostatically attracted on the wafer stage 4 without flowing of the cooling gas such as He.

After the control unit 40 determines that the temperature of the wafer 2 has reached the first temperature and cycle processing is completed for the first time, the process returns to the step S101 and it is determined whether the remaining processing amount has reached zero. As described above, when the control unit 40 determines that the remaining processing amount has reached zero, the etching processing of the film to be processed of the wafer 2 is ended, and if it is determined that the remaining processing amount is larger than zero, the process proceeds to the step S102 again and the processing of any one of the process A and the process B is performed.

Specifically, when the determination result of the step S102 is “remaining processing amount is large”, the processing is performed in the order of steps S103B, S104B, S105B, S106B, S108, and S109 as described above. On the other hand, when the determination result of the step S102 is “remaining processing amount is small”, the processing is performed in the order of steps S103A, S104A, S105A, S106A, S107A, S108, and S109.

Although not shown in FIG. 2, when the processing of the wafer 2 is ended, the supply of the cooling gas supplied from the mass flow controller 50-4 is stopped under the control of the control unit 40. Further, under the control of the control unit 40, a process of discharging the He gas from the back surface of the wafer 2 by opening a valve 52 disposed on a waste gas path connecting the He gas supply path and the vacuum exhaust pipe 16 from a closed state and a process of releasing the electrostatic attraction of the wafer 2 are performed.

Thereafter, the processed wafer 2 is transferred to a transfer robot through a wafer loading-and-unloading gate (not shown) of the base chamber 11, and an unprocessed wafer 2 to be processed next is loaded. As a matter of course, when there is no unprocessed wafer 2 to be processed next, the wafer loading-and-unloading gate is closed, and the operation of the semiconductor device by the semiconductor manufacturing apparatus 100 is stopped.

In the present embodiment, the second temperature, the third temperature, and the fourth temperature, which are set in each of the process A and the process B, do not necessarily have to be the same value in the process A and the process B. Before the processing of the wafer 2, an appropriate range of the temperature is set by careful consideration in advance. The control unit 40 sets the temperature for each step as a processing condition of the wafer 2 in the process A and the process B of each cycle according to a specification of the film to be processed of the target wafer 2.

The process of the step S103A or the step S103B, which is the first process of the flow of the process A and the flow of the process B of the present example shown in FIG. 2, is a process of forming the physical adsorption layer of the complexing gas on the surface of the film to be processed containing the typical metal element other than the tetravalent element, for example, the Al₂O₃ film, and is performed while maintaining the wafer 2 at the first temperature equal to or lower than the boiling point of the complexing gas. Details of the complexing gas will be described later, and the complexing gas is a gas (organic gas) containing an organic substance containing, as a main active component, an organic compound having a Lewis basic partial molecular structure in a molecule. When, for example, an organic gas having a boiling point of approximately 200° C. is used as such an organic gas, the process of the step S103A or the step S103B is performed while the wafer 2 is maintained for example, approximately 180° C. or a temperature within a range in which a maximum value is 200° C. or lower.

In the above process of the present embodiment, when methoxyacetic acid is used, which is an example of the organic substance having the boiling point of approximately 200° C. suitable as the main component of the gas (organic gas) containing the organic substance containing the organic compound having the Lewis basic partial molecular structure in the molecule as the main active component, the first temperature is preferably in a range from approximately 100° C. to 180° C., and more preferably in a range from 120° C. to 160° C. When the first temperature is lower than 100° C., at a stage of proceeding to the step S104A or the step S104B which is the next process, it takes a long time to change the temperature of the wafer 2 to a value to be achieved by such steps, and thus productivity may be lowered. On the other hand, when the first temperature is higher than 180 ºC, adsorption efficiency (adhesion characteristics) of methoxyacetic acid decreases, and therefore, it is necessary to increase a gas flow rate of methoxyacetic acid in order to adsorb a predetermined amount in a short time, which may increase gas consumption and operating cost.

As shown in FIGS. 2 to 4, after the physical adsorption layer is formed in the step S103A or the step S103B of the present embodiment, power is supplied from the IR lamp power supply 64 to the IR lamp 62 in the step S104A or S104B, the wafer 2 is irradiated with the electromagnetic waves from the IR lamp 62 to be heated, and the temperature of the wafer 2 rapidly rises to the second temperature. In the present embodiment, in these processes, the adsorption state of the complexing gas on the surface of the film to be processed containing the typical metal element other than the tetravalent element, for example, the Al₂O₃ film, is changed from the physical adsorption state to the chemical adsorption state to form the surface chemical adsorption layer. The temperature rise of the wafer 2 in this process gives activation energy by heat to the molecules of the complexing gas adsorbed on the surface of the film to be processed, thereby causing a change in the adsorption state.

The second temperature is determined in consideration of an influence of both a state of the surface of the film to be processed containing the typical metal element other than the tetravalent element, for example, the Al₂O₃ film, and a characteristic (reactivity) of the complexing gas. When, for example, the complexing gas containing methoxyacetic acid as the main component is supplied to the Al₂O₃ film that serves as the film to be processed, a suitable range of the second temperature is approximately from 120° ° C. to 210° C. In the case where the complexing gas containing methoxyacetic acid as the main component is used, when the temperature is lower than 120° ° C., a time required for conversion to the chemical adsorption layer becomes long, a time required for the etching processing of the wafer 2 becomes long, and thus processing efficiency is impaired, and when the temperature exceeds 210° C., the complexing gas is converted into the organometallic complex instead of staying in the chemical adsorption state, and there is a risk that accuracy of a remaining film thickness of the film layer to be processed will be lowered after the processing.

Next, as a processing condition in included information acquired by the control unit 40, when an etching amount of the target film of the processing to be performed on the wafer 2 is large, for example, when a thickness of larger than 2 nm is to be removed from the surface of the Al₂O₃ film by etching, the following processing is performed as the processing of the step S105B. That is, for example, in a state where the supply of the complexing gas (for example, methoxyacetic acid or the like) is maintained, the heating by the irradiation with the electromagnetic waves from the IR lamp 62 is further continued, the power supplied to the IR lamp 62 is increased so as to increase an amount of radiation of the electromagnetic waves per time unit, and thus the temperature of the wafer 2 is increased to the fourth temperature.

In the present embodiment, the fourth temperature is set to a temperature that is lower than a temperature at which thermal decomposition of the volatile organometallic complex generated by the reaction between the surface material of the film to be processed containing the typical metal element other than the tetravalent element, for example, the film to be processed containing Al₂O₃ and the complexing gas occurs, and is equal to or higher than a temperature at which sublimation or evaporation starts. Further, in the process B of the present example, after the temperature of the wafer 2 is set to the fourth temperature in the step S105B, the temperature of the wafer 2 is maintained at the fourth temperature at least in a period until the supply of the complexing gas is stopped in the step S106B. By such a flow, the surface of the film to be processed containing the typical metal element other than the tetravalent element, for example, the film containing the Al₂O₃ film on the wafer 2 is substantially continuously etched in the process B.

On the other hand, as the processing condition included in the information acquired by the control unit 40, when the etching amount of the target film of the processing to be performed on the wafer 2 is small, for example, when processing of removing the Al₂O₃ film by a thickness of 0.2 nm is performed, the following series of processes are performed as processing after the step 105A. That is, after the supply of the complexing gas such as methoxyacetic acid is stopped and the inside of the processing chamber 1 is exhausted (step S105A), the wafer 2 is heated by using the IR lamp 62 and the temperature thereof is increased to the third temperature (step S106A). When the temperature of the Al₂O₃ film is maintained at the third temperature for a predetermined period, the chemical adsorption layer formed on the surface of the Al₂O₃ film is converted into the organometallic complex.

The third temperature of the present embodiment is set to a temperature in a range equal to or higher than the second temperature and lower than the evaporation start temperature of the organometallic complex molecules. Similarly to the other temperatures, the third temperature is set within the above appropriate temperature range in consideration of stability of temperature control of the semiconductor manufacturing apparatus 100 or the control unit 40, accuracy of temperature detection of the wafer 2 or the wafer stage 4 using the thermocouple thermometer 71 or an alternative temperature detector, and the like.

According to the study of the present inventors, in the case of the etching processing using the Al₂O₃ film as the film to be processed containing the typical metal element and using a mixed gas containing methoxyacetic acid as a main component as the complexing gas, the evaporation start temperature of the organometallic complex molecules is around 270° C. In view of this, the present inventors determine that a value within a range from 120° C. to approximately 250° C. is appropriate as the third temperature, and in the present embodiment, the value within the temperature range is set as the third temperature.

Further, as the step S106A, the irradiation of the wafer 2 with the electromagnetic waves from the IR lamp 62 is continued, and the wafer 2 is maintained at the third temperature for a predetermined period, and then, as the processing of the step S107A, an output of the IR lamp 62 and intensity of the radiated electromagnetic waves per unit time are increased, and thus the wafer 2 is further heated. As a result, the temperature of the wafer 2 is increased to the higher fourth temperature, and this temperature is maintained for a predetermined period. By maintaining the temperature of the wafer 2 at the fourth temperature, the organometallic complex converted from the chemical adsorption layer is volatilized and removed from the upper surface of the film layer to be processed.

In the present example, when the step S107A is started, only one to several layers, more specifically, at most approximately five layers of the organometallic complex are generated, and therefore, after the temperature reaches the fourth temperature, the organometallic complex constituting the upper surface of the film to be processed is rapidly volatilized and removed. When the organometallic complex layer is removed, one cycle is completed as a reaction of etching or removing the film to be processed in the present embodiment when the unreacted film to be processed containing the typical metal element or a layer of a silicon compound or the like disposed under the film to be processed directly below the organometallic complex layer is exposed.

In the case of the processing using, for example, the Al₂O₃ film as the film to be processed containing the typical metal element and using the mixed gas containing methoxyacetic acid as the main component as the complexing gas, a suitable value of the fourth temperature is selected from a range from 270° ° C. to 400° C. When the temperature is lower than 270° ° C., a rate of sublimation and evaporation is slow and the processing efficiency is impaired, whereas when the temperature is higher than 400° C., a part of the complex is thermally decomposed and thus becomes foreign matter in the process of sublimation and evaporation of the organometallic complex, and there is a high possibility that the foreign matter will adhere to the front surface of the wafer 2 or the inside of the processing chamber 1.

Next, another example of the flow of the etching processing of the above embodiment will be described.

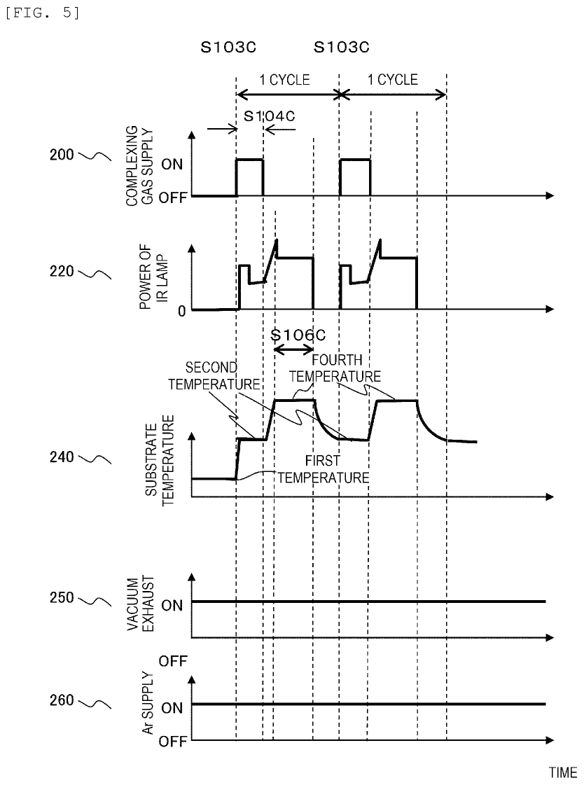

FIG. 5 is a time chart schematically showing an operation flow relative to a time transition of etching processing of a film to be processed performed by a semiconductor manufacturing apparatus according to a modification of the present embodiment. In this modification, differences will be mainly described with reference to FIGS. 1 and 2.

In this example, as in the above embodiment, after the wafer 2 is introduced into the processing chamber 1 and transferred to the stage 4, He gas is introduced into the gap between the wafer 2 and the stage 4 as necessary to adjust the temperature of the wafer 2 in a state where the wafer 2 is placed on the dielectric film constituting the placement surface of the stage 4 and held by attraction. When the control unit 40 detects that a temperature of each temperature measurement detector of the stage 4 having built-in temperature detectors has reached a predetermined temperature set in advance, for example, the first temperature a temperature lower than the first temperature in this example (cooled in this example), etching processing is started in order to form a circuit structure of a semiconductor device by processing the film to be processed containing the typical metal element other than the tetravalent element, for example, the Al₂O₃ film disposed in advance on the front surface of the wafer 2.

First, as in the embodiment shown in FIG. 2, the steps S101 and S102 are sequentially performed, and a process of detecting the remaining processing amount of the etching processing and a process of comparing the remaining processing amount with a predetermined threshold value are performed.

Next, after the control unit 40 having received outputs from the temperature detectors in the stage 4 determines that the temperature of the wafer 2 is equal to or lower than the predetermined first temperature, a process (step S103C) of supplying the complexing gas as the processing gas into the processing chamber 1 and adsorbing molecules of the complexing gas onto the surface of the film to be processed containing the typical metal element, for example, the Al₂O₃ film to form the physical adsorption layer is started.

In this example, after the step S103C is started, power is rapidly supplied to the IR lamp 62 to emit infrared light, thereby heating the wafer 2 to rapidly increase the temperature thereof to the second temperature. In the step S103C, the supply of the complexing gas to the upper surface of the wafer in the processing chamber 1 is continued while the wafer 2 is maintained at the second temperature for a predetermined period. Therefore, during the period of the step S103C, a reaction of forming the physical adsorption layer of the complexing gas component on the surface of the film to be processed containing the typical metal element and a conversion reaction of converting the physical adsorption layer into the chemical adsorption layer continuously proceed in parallel.

At this time, as described above, since a rate of diffusion of the complexing gas molecules into the inside of the film to be processed through the chemical adsorption layer formed on the surface of the film to be processed is slow, a film thickness of the chemical adsorption layer is saturated relative to a processing time. After the film thickness of the chemical adsorption layer is saturated by performing processing of continuing the supply of the complexing gas for a predetermined time while maintaining the temperature substantially at the second temperature, the supply of the complexing gas is stopped in a next step (referred to as a step S104C).

In a process flow shown in FIG. 5, the exhaust mechanism 15 is driven at a stage before the step S103C of supplying the complexing gas is performed, in other words, from a time point at which the temperature of the wafer 2 becomes equal to or lower than the predetermined first temperature, and the internal pressure of the processing chamber 1 is maintained in a depressurized state by using the pressure adjustment mechanism 14, the vacuum exhaust pipe 16, and the like. Therefore, when the supply of the complexing gas is stopped in the step S104C, all of the complexing gas in an unadsorbed state or a physically adsorbed state is exhausted and removed to the outside of the processing chamber 1 except that the complexing gas in the state of being chemically adsorbed on the surface is left. It is preferable to continuously supply a small amount of Ar gas into the processing chamber 1 in order to promote the exhaust and removal of the etching organic gas physically adsorbed to an inner wall or the like of the chamber 1 to the outside of the processing processing chamber 1.

A supply amount of the Ar gas and the pressure in the processing chamber 1 need to be appropriately adjusted according to compositions of the film to be processed and the complexing gas, and when the Al₂O₃ film is etched by using the complexing gas containing methoxyacetic acid as the main component, the supply amount of the Ar gas is preferably 200 sccm or smaller, and the pressure in the processing chamber is preferably approximately 0.5 Torr to 3.0 Torr, and more preferably, the supply amount of the Ar gas is approximately 100 sccm, and the pressure in the processing chamber is approximately 1.5 Torr. When the supply amount of Ar is increased to exceed 200 sccm, an effective concentration of the complexing gas in the processing chamber 1 decreases, efficiency of adsorption to the surface of the film to be processed decreases, and thus a risk of causing a decrease in an etching rate increases. In addition, when the pressure in the processing chamber is lower than 0.5 Torr, a residence time of the complexing gas in the processing chamber 1 is shortened, and thus a risk of lowering use efficiency of the complexing gas increases. When the pressure in the processing chamber is adjusted to exceed 3 Torr, the supply amount of Ar is set to 200 sccm or larger, the efficiency of adsorbing the complexing gas on the surface of the film to be processed decreases, and thus the risk of causing the decrease in the etching rate increases.

Next, a step (referred to as a step S106C) of increasing the temperature to the fourth temperature by infrared heating using the IR lamp 62 and maintaining the temperature substantially at the fourth temperature for a predetermined time is performed. In the process of increasing the temperature to the fourth temperature and maintaining the temperature, the conversion from the chemical adsorption layer to the organometallic complex and the volatilization removal of the organometallic complex proceed. When the Al₂O₃ film serving as the film to be processed and the complexing gas containing methoxyacetic acid as the main component are used, a suitable range of the fourth temperature is from 270° ° C. to 400° C. When the temperature is lower than 270° C., sublimation and evaporation are slow and a practical etching rate cannot be obtained, whereas when the temperature is higher than 400° C., a part of the organometallic complex is thermally decomposed into foreign matter at a location of 400° C. or lower in the process of the sublimation and the evaporation of the organometallic complex, and thus a risk of re-adhesion to the front surface of the wafer 2 or the inside of the processing chamber 1 increases.

When the volatilization removal of the organometallic complex is completed and the unreacted film to be processed containing the typical metal element or the layer of the silicon compound or the like disposed under the film to be processed directly below the organometallic complex is exposed, processing of one cycle is completed. Thereafter, when the infrared heating using the IR lamp 62 is stopped, the temperature starts to decrease due to heat radiation from the wafer 2. When the temperature of the wafer 2 reaches the second temperature or a temperature equal to or lower than the second temperature, the processing of one cycle is completed.

Thereafter, the second and subsequent cycle processing starting from the processing of the step S103C via the step S102 are repeated for a desired number of times, whereby etching of a predetermined film thickness can be implemented. The process flow shown in FIG. 5 is a simplified version of the process flow shown in FIG. 4, in which a time per cycle is shortened by reducing levels of the temperature and narrowing a temperature range of the cooling processing in the step S108 that is particularly time-consuming.

Next, still another modification will be described.

On the front surface of the wafer 2 used in this modification, in addition to a first film to be processed containing a typical metal element, for example, an Al₂O₃ film, which is processed into a desired pattern shape, a second film to be processed containing a transition metal element lower than the fifth period of the periodic table, for example, an La₂O₃ film, is formed in advance, and a part thereof is exposed. In this embodiment, in order to selectively etch the first film to be processed, for example, the Al₂O₃ film containing the typical metal element, and the second film to be processed, for example, the La₂O₃ film containing the transition metal element, a first complexing gas for etching the first film to be processed and a second complexing gas for etching the second film to be processed are appropriately used.

More specifically, the wafer 2 is in a state where the Al₂O₃ film (1.0 mm thick) containing the typical metal element as an example of the first film to be processed and the La₂O₃ film (1.0 nm thick) containing the transition metal element as an example of the second film to be processed are alternately stacked, and a part of a stacked portion of Al₂O₃—La₂O₃—Al₂O₃—La₂O₃ is exposed. The wafer 2 having such a multilayer structure is introduced into the processing chamber 1 in the same manner as described above, and is held, attracted and fixed at a predetermined position on the wafer stage 4, and an etching processing amount of each layer is determined. In the case where process selection of the process A or the process B described with reference to FIG. 2 is performed according to a thickness to be processed, and a heterogeneous stacked portion is selectively etched when the respective processing is performed in the same manner as described above, in the present modification, a step of etching only the Al₂O₃ film (1.0 mm thick) and a step of etching only the La₂O₃ film (1.0 nm thick) are sequentially performed.

Hereinafter, an example of a processing flow in which only the Al₂O₃ film (1.0 nm thick) is etched, and then only the La₂O₃ film (1.0 nm thick) is etched will be described. First, as the first complexing gas suitable for etching the Al₂O₃ film, for example, methoxyacetic acid is supplied from a mass flow controller (not shown) to etch the Al₂O₃ film. At this time, regardless of the film thickness to be removed by etching, first, only an outermost surface layer is etched following the process A of FIG. 2, and at the stage of the step S103A, only one to several layers of an organic Al complex layer in which methoxyacetic acid and Al are combined and an organic La complex layer in which methoxyacetic acid and La are combined are generated by a reaction with methoxyacetic acid, respectively, on an outermost surface layer of the Al₂O₃ film and an outermost surface layer of the La₂O₃ film.

At this time, the organic Al complex formed by combining methoxyacetic acid and Al is relatively thermally stable, and is removed by sublimation from around 270° C. as described above. Meanwhile, since the organic La complex derived from methoxyacetic acid and La is thermally decomposed at 250° C. or higher, the organic La complex derived from methoxyacetic acid and La is not sublimated and removed but is thermally decomposed and converted into a carbon-based residue selectively adhered only to the surface of the La₂O₃ film under the condition which the organic Al complex formed by combining methoxyacetic acid and Al is sublimated and removed. When the carbon-based residue is generated only on the surface of the La₂O₃ film in this manner, the carbon-based residue acts as a hard mask, and the La₂O₃ film is not etched after a second cycle.

On the other hand, since no carbon-based residue is generated on the surface of the Al₂O₃ film, the etching of the Al₂O₃ film proceeds after the second cycle. In the second cycle, a residual film to be processed is determined in the step S102. If it is determined that a remaining film amount is larger than a predetermined threshold value of 0.5 nm, substantially continuous etching is performed at least once in the process B of FIG. 2, and thereafter, after a third cycle, the processing proceeds according to the process flow of FIG. 2 until the Al₂O₃ film is etched by a desired film thickness. As described above, in the processing after the second cycle, since the carbon-based residue is selectively fixed to the surface of the La₂O₃ film, the La₂O₃ film is not etched.

When the etching of the Al₂O₃ film having the desired thickness is completed, first, the carbon-based residue fixed on the La film is removed by using a residue removal processing technique such as ashing or plasma cleaning. The ashing or the plasma cleaning processing is preferably used in combination with a method (not shown) for detecting an end point of the removal of the carbon-based residue. In the present modification, for example, an end point detection method such as analyzing a plasma spectrum can be used.

Next, as the second complexing gas suitable for etching the La₂O₃ film, for example, a mixed gas of hexafluoroacetylacetone and diethylene glycol dimethyl ether described in JP-A-2018-186149 is supplied from a mass flow controller (not shown) to etch the La₂O₃ film. At this time, the second complexing gas does not react with the outermost surface layer of the Al₂O₃ film, and the volatile organic Al complex layer is not formed. Meanwhile, the second complexing gas reacts with the outermost surface layer of the La₂O₃ film to form a volatile organic La complex layer. Therefore, the La₂O₃ film can be etched and removed by sequentially applying the process B and the process A of FIG. 2, similarly to the flow of etching and removing the Al₂O₃ single layer film, except that the mixed gas of hexafluoroacetylacetone and diethylene glycol dimethyl ether is supplied from the mass flow controller (not shown).

In this way, by appropriately using the various types of gases, namely methoxyacetic acid, hexafluoroacetylacetone, and diethylene glycol dimethyl ether, the stacked film of Al₂O₃—La₂O₃—Al₂O₃—La₂O₃ is removed. In the case of a combination of film materials and a film thickness to be removed other than those exemplified here, if an appropriate complexing gas is appropriately selected in advance, it is possible to perform etching on a large number of types of stacked films.

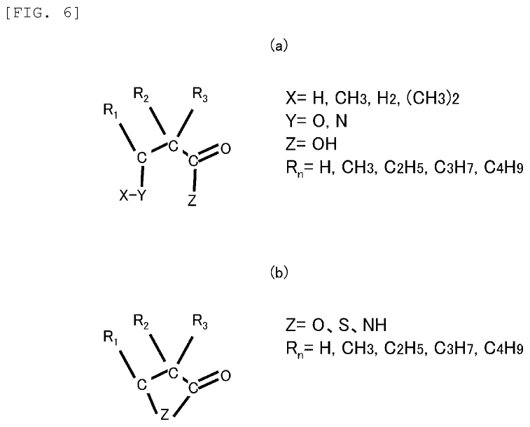

Next, components of the complexing gas suitable for the invention of the present application will be described with reference to FIG. 6. FIG. 6 is a drawing schematically showing an example of a molecular structure of the organic gas used as the processing gas in the present embodiment or the modifications shown in FIGS. 1 to 5.

A main active component of the complexing gas is an organic compound capable of forming at least two or more coordination bonds with a typical metal atom, that is, a so-called multidentate ligand molecule, and a liquid obtained by mixing at least one or a plurality of types of components which do not contain halogen and have a structure of the following molecular structural formula (1) or molecular structural formula (2) and, if necessary, dissolving the components in an appropriate diluent is used as the chemical liquid 44 that serves as the raw material of the complexing gas. By using the liquid dissolved in the diluent, the diluent promotes vaporization of the component having the structure of the following molecular structural formula (1) or molecular structural formula (2), and the vaporized diluent functions as a carrier gas, thereby enabling smooth supply.

Molecular structural formula (1): the molecular structure shown in (a) of FIG. 6, which has a carboxyl group, and has an OH group, an OCH₃ group, an NH₂ group, an N (CH₃)₂ group, or the like that is a partial structure having Lewis basicity on a carbon atom adjacent to and bonded to a carbon atom to which the carboxyl group is bonded and having an unshared electron pair.

Molecular structural formula (2): the molecular structure shown in (b) of FIG. 6, which is an aliphatic four-membered ring compound having a carbonyl group, the carbonyl group being bonded to O, S, or NH that is a partial structure having an unshared electron pair.

The molecular structure shown in (a) of FIG. 6 is characterized by having a structure in which the carboxyl group, which is a partial structure having Lewis acid characteristics, and the OH group, the OCH₃ group, or the NH₂ group, which is a partial structure having Lewis basicity, are included in the same molecule and thus acid and base are partially neutralized in the molecule. Such an intramolecular partial neutralization structure facilitates volatilization at a relatively low temperature, and thus vaporization can be performed even with the organic gas vaporization supplier 47 that has a relatively simple structure.

The case of X═CH₃, Y═O, R1═R2═R3═H, and 2═OH in (a) of FIG. 6 is methoxyacetic acid. In methoxyacetic acid, an unshared electron pair of Y═O and an unshared electron pair of OH of the carboxyl group at a position facing the unshared electron pair of Y═O are donated to a metal element to form two coordinate bonds, thereby generating the organometallic complex. As described above, since the coordination bonds are electron-donation+back-donation type strong bonds, and the bonds are formed at the two positions, the obtained methoxyacetic acid metal complex is a thermally stable complex compound.

In a metal acetate or a metal formate obtained by a reaction of simple acetic acid or simple formic acid with a typical metal, the number of bonds is one. In the above example, the organometallic complex intermediately generated has significantly improved thermal stability as compared with such carboxylic acid salts, and as a result, has a property of being easily removed by evaporation.

The molecular structure shown in (b) of FIG. 6 is the aliphatic four-membered ring compound having the carbonyl group. O, S, or NH, which is the partial structure having the unshared electron pair, is bonded to the carbonyl group. Since a molecular cross-sectional area is smaller than that of the structure of (a) of FIG. 6, the compound is more easily volatilized at a lower temperature than that of the compound of (a) of FIG. 6, and the compound can be efficiently vaporized even by the organic gas vaporization supplier 47 that has the relatively simple structure.

When a substance having this molecular structure is brought into contact with a film material containing a typical metal element, a reaction of releasing strain energy caused by a small membered ring is induced, and an organometallic complex in which the typical metal element is incorporated into the ring is obtained. A bond formed at this time is an electron-donation+back-donation type strong bond, and since the bond is formed at two positions, the obtained cyclic organometallic complex is a complex compound having high thermal stability, and as a result, having a property of being easily removed by evaporation.

According to the present embodiment, in the generated thermally stable complex compound, a positive charge of the metal element of the film to be etched is electrically neutralized by the unshared electron pair donated from the Lewis basic partial molecular structure contained in the etching gas. As a result, an electrostatic attractive force acting between adjacent molecules disappears, thus volatility (sublimability): is increased, and the etching can be performed with high efficiency.

In addition, since the metal complex having high volatility is generated by exposing the film to be etched to the gas having the Lewis basic partial molecular structure in the molecule, processing can proceed in a short time and efficiency of the processing can be improved as compared with a technique in related art in which two processes are performed by reactions using two different gases with a reaction downtime in between.

Further, the metal complex compound having high volatility has relatively high stability against heat, and is prevented from being thermally decomposed again after volatilization and staying in the chamber to generate foreign matter, so that processing yield is improved. In this way, according to the present invention, it is possible to provide the semiconductor manufacturing method or the semiconductor manufacturing apparatus by which surface roughening of a metal film is prevented while highly efficient etching is implemented with improved yield.

### REFERENCE SIGNS LIST

1 processing chamber
2 wafer
3 discharge region
4 stage
5 shower plate
6 ceiling plate
10 plasma
11 base chamber
12 quartz chamber
14 pressure adjustment mechanism
15 exhaust mechanism
16 vacuum exhaust pipe
17 gas dispersion plate
20 high frequency power supply
22 matching unit
25 high frequency cut filter
30 electrostatic attraction electrode
31 DC power supply
34 ICP coil
38 chiller
39 coolant flow path
40 control unit
41 calculation unit
44 chemical liquid
45 tank
46 heater
47 organic gas vaporization supplier (processing gas supply apparatus)
50 gas supply mass flow controller
51 mass flow controller control unit
52, 53, 54 valve
60 container
62 IR lamp
63 reflection plate
64 IR lamp power supply
70 thermocouple
71 thermocouple thermometer
74 light transmission window
75 gas flow path
78 slit plate
81 O-ring
92 optical fiber
93 external IR light source
94 optical path switch
95 optical distributor
36 spectroscope
97 detector
98 optical multiplexer
100 semiconductor manufacturing apparatus

1. A semiconductor manufacturing method comprising:
a step of placing a wafer in a processing chamber, the wafer having a film to be processed containing a typical metal element disposed on a surface thereof;
a step of supplying an organic gas into the processing chamber, the organic gas containing an organic compound having a Lewis basic partial molecular structure; and
a step of increasing and maintaining a temperature of the wafer, wherein
the step of increasing and maintaining the temperature of the wafer includes: a volatilization step of vaporizing and desorbing an organometallic complex film formed by a reaction between the film and the organic gas containing the organic compound.

2. The semiconductor manufacturing method according to claim 1, wherein
the formation of the organometallic complex film and the vaporization of the organometallic complex film are repeated by maintaining the temperature of the wafer at a predetermined temperature while supplying the organic gas containing the organic compound.

3. The semiconductor manufacturing method according to claim 1, wherein
after the supply of the organic gas containing the organic compound is stopped, the temperature of the wafer is increased and maintained, and the volatilization step is performed.

4. The semiconductor manufacturing method according to claim 3, wherein
the temperature of the wafer is increased in at least two stages.

5. The semiconductor manufacturing method according to claim 1, wherein
the film is formed of a plurality of films to be processed containing different metal elements, and is selectively etched by appropriately using the organic gas containing the organic compound that reacts with each of the films to be processed to form an organometallic complex film.

6. The semiconductor manufacturing method according to claim 1, wherein
a remaining processing amount of the film is determined,
when the remaining processing amount of the film exceeds a threshold value, a step of repeating the formation of the organometallic complex film and the vaporization of the organometallic complex film by increasing the temperature of the wafer to a predetermined temperature and maintaining the temperature of the wafer at the predetermined temperature while supplying the organic gas containing the organic compound is performed, and
when the remaining processing amount of the film is equal to or smaller than the threshold value, the temperature of the wafer is increased and maintained, and the volatilization step is performed after the supply of the organic gas containing the organic compound is stopped.

7. The semiconductor manufacturing method according to claim 1, wherein
the organic gas contains, as a component, an organic compound which is a multidentate ligand molecule that contains no halogen, has a carboxyl group, and has an OH group, an OCH₃ group, an NH₂ group or an N(CH₃)₂ group that is a partial structure having Lewis basicity on a carbon atom adjacent to and bonded to a carbon atom to which the carboxyl group is bonded and having an unshared electron pair.

8. The semiconductor manufacturing method according to claim 1, wherein
the organic gas is a gas containing methoxyacetic acid.

9. The semiconductor manufacturing method according to claim 1, wherein
the organic gas is a gas containing, as a component, an organic processed product compound that is an aliphatic four-membered ring compound having a carbonyl group, the carbonyl group being bonded to O, S, or NH that is a partial structure having an unshared electron pair.

10. A semiconductor manufacturing apparatus comprising:
a container including a processing chamber therein;
a stage that is disposed in the processing chamber and on which a wafer is disposed, the wafer having a film to be processed containing a typical metal element disposed on a surface thereof;
a processing gas supply apparatus configured to supply an organic gas into the processing chamber, the organic gas containing a Lewis basic organic compound; and
a heating apparatus configured to heat the wafer,
the semiconductor manufacturing apparatus further comprising: a control unit configured to operate the heating apparatus so as to increase and maintain a temperature of the wafer in accordance with a supply operation of the organic gas containing the organic compound.

11. The semiconductor manufacturing apparatus according to claim 10, wherein
the control unit controls the heating apparatus such that the temperature of the wafer is increased to a temperature at which an organometallic complex film is vaporized and desorbed, the organometallic complex film being formed by supplying the organic gas containing the organic compound into the processing chamber by the processing gas supply apparatus so as to adsorb the organic gas onto the film.

12. The semiconductor manufacturing apparatus according to claim 11, wherein
the control unit performs control such that a remaining processing amount of the film is determined,
when the remaining processing amount of the film exceeds a threshold value, a step of repeating the formation of the organometallic complex film and the vaporization of the organometallic complex film by increasing the temperature of the wafer to a predetermined temperature and maintaining the temperature of the wafer at the predetermined temperature while supplying the organic gas containing the organic compound is performed, and
when the remaining processing amount of the film is equal to or smaller than the threshold value, the temperature of the wafer is increased and maintained after the supply of the organic gas containing the organic compound is stopped.

13. The semiconductor manufacturing apparatus according to claim 10, wherein
the organic gas contains, as a component, an organic compound which is a multidentate ligand molecule that contains no halogen, has a carboxyl group, and has an OH group, an OCH₃ group, an NH₂ group or an N(CH₃)₂ group that is a partial structure having Lewis basicity on a carbon atom adjacent to and bonded to a carbon atom to which the carboxyl group is bonded and having an unshared electron pair.

14. The semiconductor manufacturing apparatus according to claim 10, wherein
the organic gas is a gas containing methoxyacetic acid.

15. The semiconductor manufacturing apparatus according to claim 10, wherein
the organic gas is a gas containing, as a component, an organic compound that is an aliphatic four-membered ring compound having a carbonyl group, the carbonyl group being bonded to O, S, or NH that is a partial structure having an unshared electron pair.
